(19) United States
(12) Patent Application Publication
(10) Pub. No.: US 2014/0292148 A1
(43) Pub. Date: Oct. 2, 2014

(54) ACOUSTIC MATCHING BODY, ULTRASONIC PROBE, AND ULTRASONIC IMAGING DEVICE

(71) Applicant: Seiko Epson Corporation, Tokyo (JP)

(72) Inventor: Tomoaki NAKAMURA, Chino (JP)

(73) Assignee: SEIKO EPSON CORPORATION, Tokyo (JP)

(21) Appl. No.: 14/224,440

(22) Filed: Mar. 25, 2014

(30) Foreign Application Priority Data
Mar. 29, 2013 (JP) 2013-075339

(51) Int. Cl. H01L 41/053

(52) U.S. Cl. CPC H01L 41/053
USPC 310/334

(57) ABSTRACT

An acoustic matching body includes an element connection surface connectable to an ultrasonic wave emission surface of an ultrasonic transducer element, a curved surface that has a shape of a convexity above the element connection surface and is formed by generatrices parallel to one another, and a slit-like through hole that passes through between the element connection surface and the curved surface.

### BACKGROUND

1. Technical Field

The present invention relates to an acoustic matching body and an ultrasonic probe, and also to an ultrasonic imaging device and the like.

2. Related Art

An ultrasonic diagnostic device, which is a specific example of an ultrasonic imaging device, is generally known. The ultrasonic diagnostic device is used in, for example, forming an image of a body tissue. To form the image, an ultrasonic probe is pressed against a surface of a body. At this time, the spacing between the ultrasonic probe and the surface of the body is filled with an acoustic coupling material (medium), such as water, instead of the air. The acoustic coupling material plays a role in matching the acoustic impedance of the ultrasonic probe with the acoustic impedance of a human body. In this way, ultrasonic waves can be efficiently transmitted between the ultrasonic probe and the surface of the body in accordance with the function of the acoustic coupling material.

According to JP-A-9-262237, which is an example of related art, minute concavities and convexities are formed on a distal end surface of an ultrasonic probe, that is to say, an emission surface from which ultrasonic waves are emitted. A water supply opening of a water supply nozzle is arranged at the center of the emission surface. Water is supplied from the water supply opening for ultrasonic diagnosis. The spacing between the emission surface and the surface of the body is filled with the supplied water.

According to the description of JP-A-9-262237, the water is intended to diffuse due to the capillary action associated with the minute concavities and convexities. The water is retained on the emission surface due to the capillary action. However, when the emission surface is pressed against the surface of the body, the minute concavities and convexities could possibly fit in with and be blocked by the surface of the body. In this case, when the emission surface moves with respect to the surface of the body, the water cannot be replenished sufficiently between the emission surface and the surface of the body. Moreover, if the emission surface does not have a circular shape with the water supply opening at the center thereof, the water escapes from an outline in the vicinity of the water supply opening and hence cannot spread far from the water supply opening.

### SUMMARY

An advantage of at least one aspect of the invention makes it possible to provide an acoustic matching body that can sufficiently distribute an acoustic coupling material between an outer front surface thereof and a soft subject.

(1) A first aspect of the invention relates to an acoustic matching body including: an element connection surface connectable to an ultrasonic wave emission surface of an ultrasonic transducer element; a curved surface that has a shape of a convexity above the element connection surface and is formed by generatrices parallel to one another; and a slit-like through hole that passes through between the element connection surface and the curved surface.

An acoustic coupling material (medium), such as water, spreads in the slit-like through hole, and then is supplied to the curved surface. Even when the curved surface is pressed against a soft subject, such as a surface of a body, a sufficient amount of acoustic coupling material can be supplied from the element connection surface to the curved surface. In this way, the acoustic coupling material can spread along the curved surface.

(2) It is preferable that an inner surface of the slit-like through hole has two planes that are perpendicular to the generatrices of the curved surface. The acoustic coupling material spreads along the planes perpendicular to the generatrices, and then is supplied to the curved surface.

(3) It is preferable that, in such an acoustic matching body, a supply opening that communicates with the slit-like through hole is located at a position outside a region in which the ultrasonic transducer element is arranged in a plan view in a direction normal to the element connection surface. In the case where the acoustic matching body is expected to move in a direction perpendicular to the generatrices of the curved surface, the acoustic coupling material can be supplied from the supply opening on a front side in a direction of the movement. Even during the movement, the spacing between the curved surface and the soft subject can be sufficiently filled with the acoustic coupling material.

(4) It is preferable that an inner surface of the slit-like through hole has two planes that are parallel to the generatrices of the curved surface. The acoustic coupling material spreads along the planes parallel to the generatrices, and then is supplied to the curved surface.

(5) It is preferable that, in such an acoustic matching body, a supply opening that communicates with the slit-like through hole is located at a position outside a region in which the ultrasonic transducer element is arranged in a plan view in a direction normal to the element connection surface. In the case where the acoustic matching body is expected to move in a direction of the generatrices of the curved surface, the acoustic coupling material can be supplied from the supply opening on a front side in a direction of the movement. Even during the movement, the spacing between the curved surface and the soft subject can be sufficiently filled with the acoustic coupling material.

(6) A second aspect of the invention relates to an acoustic matching body including a plurality of acoustic matching pieces that have convex curved surfaces formed by generatrices parallel to one another, base surfaces facing the curved surfaces and parallel to the generatrices, and two planes intersecting the generatrices. Here, the curved surfaces of the acoustic matching pieces have the generatrices on mutual straight lines, and the base surfaces of the acoustic matching pieces are arranged on a mutual plane while being spaced from one another.

An acoustic coupling material (medium), such as water, spreads between the acoustic matching pieces, and then is supplied to the curved surfaces of the respective acoustic matching pieces. Even when the curved surfaces are pressed against a soft subject, such as a surface of a body, a sufficient amount of acoustic coupling material can be supplied from the base surfaces to the curved surfaces. In this way, the acoustic coupling material can spread along the curved surfaces.

(7) It is preferable that the two planes are perpendicular to the generatrices. The areas of surfaces of neighboring acoustic matching pieces facing each other can be suppressed to the minimum. Consequently, the acoustic coupling material can efficiently spread between the acoustic matching pieces.

(8) It is preferable that the plurality of acoustic matching pieces are arranged while being spaced by an equal distance from one another in a direction parallel to the generatrices. The acoustic coupling material can be distributed evenly between neighboring acoustic matching pieces. In this way, the acoustic coupling material can be supplied thoroughly to the curved surfaces along the entire lengths of lines of intersections.

(9) It is preferable that the plurality of acoustic matching pieces are arranged at an equal pitch in a direction of the generatrices. In this way, the acoustic coupling material can spread thoroughly in the direction of the generatrices.

(10) It is preferable that the acoustic matching body further includes a base layer that concurrently supports the plurality of acoustic matching pieces, with a front surface of the base layer overlying the base surfaces. The base layer joins the plurality of acoustic matching pieces to one another.

(11) It is preferable that a through hole is formed in the base layer, the through hole penetrating through the base layer and opening to a position between the plurality of acoustic matching pieces. The acoustic coupling material can be supplied from the through hole to a space between any pair of acoustic matching pieces. The acoustic coupling material can spread sufficiently within such a space.

(12) It is preferable that the acoustic matching body further includes a frame that is located on outer sides of both end portions of the curved surfaces in a direction perpendicular to the generatrices, and joins the acoustic matching pieces to one another. The frame joins the plurality of acoustic matching pieces to one another.

(13) According to a third aspect of the invention, the acoustic matching body is embedded in an ultrasonic probe for use. In this case, it is sufficient for the ultrasonic probe to include the acoustic matching body.

(14) It is preferable that the ultrasonic probe further includes an emission unit that emits an acoustic coupling material. In this way, the acoustic coupling material can be supplied from the emission unit.

(15) According to a fourth aspect of the invention, the acoustic matching body is embedded in an ultrasonic imaging device for use. In this case, it is sufficient for the ultrasonic imaging device to include the acoustic matching body.

(16) It is preferable that the ultrasonic imaging device further includes an emission unit that emits an acoustic coupling material. In this way, the acoustic coupling material can be supplied from the emission unit.

### BRIEF DESCRIPTION OF THE DRAWINGS

The invention will be described with reference to the accompanying drawings, wherein like numbers reference like elements.

FIG. 1 is an external view schematically showing an ultrasonic diagnostic device, which is a specific example of an electronic device according to one embodiment.

FIG. 2 is an enlarged front view of an ultrasonic probe according to a first embodiment.

FIG. 3 is an enlarged perspective view of an ultrasonic transducer element unit.

FIG. 4 is an enlarged plan view of an acoustic lens.

FIG. 5 is an enlarged plan view of an ultrasonic device.

FIG. 6 is a cross-sectional view of the ultrasonic transducer element unit taken along the line A-A in FIG. 5.

FIG. 7, which corresponds to FIG. 6, is a cross-sectional view of the ultrasonic transducer element unit pressed against a surface of a body.

FIG. 8, which corresponds to FIG. 3, is an enlarged perspective view of an ultrasonic transducer element unit according to a modification example.

FIG. 9, which corresponds to FIG. 5, is an enlarged plan view of an ultrasonic device according to another modification example.

FIG. 10, which corresponds to FIG. 3, is an enlarged perspective view of an ultrasonic transducer element unit according to a further modification example.

FIG. 11 is a plan view of an acoustic lens according to a still further modification example.

FIG. 12 is a plan view of an acoustic lens according to a still further modification example.

FIG. 13 is a plan view of an acoustic lens according to a still further modification example.

FIG. 14 is an enlarged partial vertical cross-sectional view of an ultrasonic probe according to a second embodiment.

FIG. 15 is an enlarged partial vertical cross-sectional view of an ultrasonic probe according to one modification example of the second embodiment.

### DESCRIPTION OF EXEMPLARY EMBODIMENTS

The following describes embodiments of the invention with reference to the attached drawings. It should be noted that the present embodiments described below are not intended to unreasonably limit the contents of the invention described in the claims, and not all configurations described in the present embodiments are indispensable as solutions provided by the invention.

1. Overall Configuration of Ultrasonic Diagnostic Device

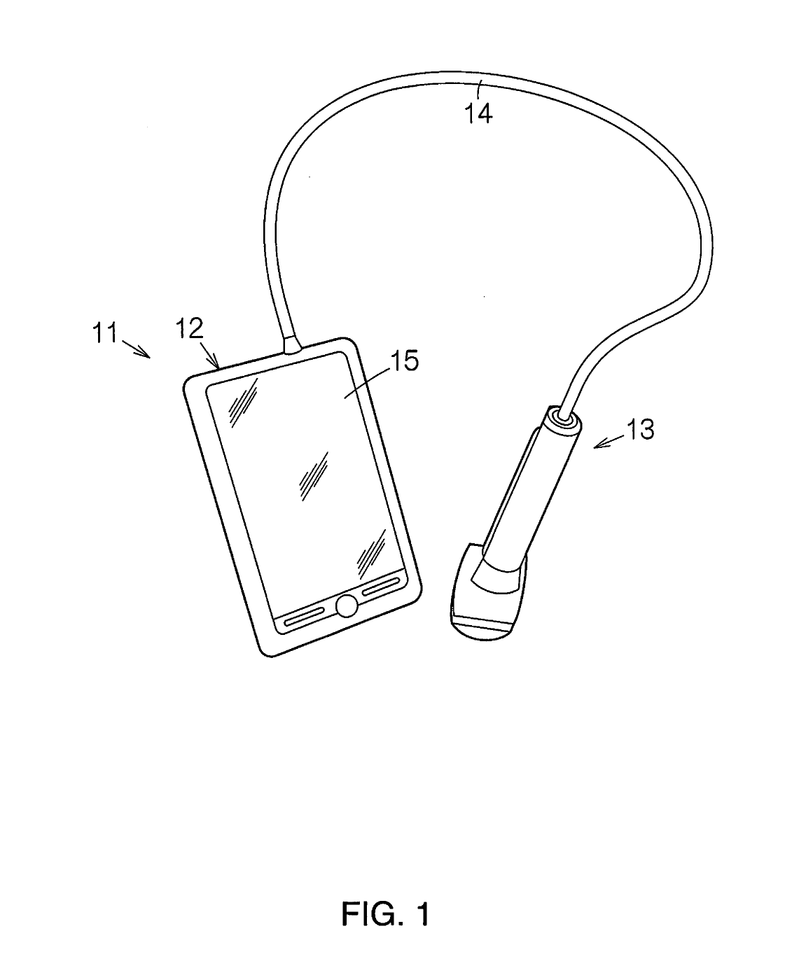

FIG. 1 schematically shows a configuration of an ultrasonic diagnostic device 11, which is a specific example of an electronic device according to one embodiment of the invention. The ultrasonic diagnostic device 11 includes a device terminal 12 and an ultrasonic probe (probe) 13. The device terminal 12 and the ultrasonic probe 13 are connected to each other by a cable 14. The device terminal 12 and the ultrasonic probe 13 exchange electrical signals with each other via the cable 14. A display panel 15 is embedded in the device terminal 12. A screen of the display panel 15 is exposed at a front surface of the device terminal 12. As will be described later, the device terminal 12 generates an image on the basis of ultrasonic waves detected by the ultrasonic probe 13. A visualized detection result is displayed on the screen of the display panel 15.

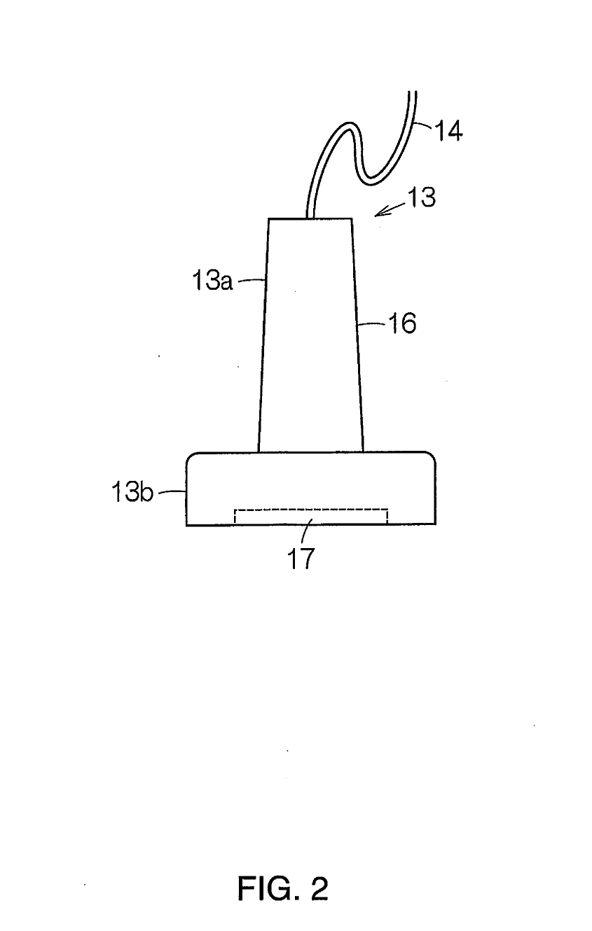

As shown in FIG. 2, the ultrasonic probe 13 includes a housing 16. The housing 16 accommodates an ultrasonic transducer element unit (hereinafter “element unit”) 17. A front surface of the element unit 17 can be exposed at a front surface of the housing 16. The element unit 17 outputs ultrasonic waves from the front surface thereof, and receives reflected waves of the ultrasonic waves. The ultrasonic probe 13 can further include a probe head 13b that is detachably joined to a probe body 13a. In this case, the element unit 17 can be embedded in the housing 16 of the probe head 13b.

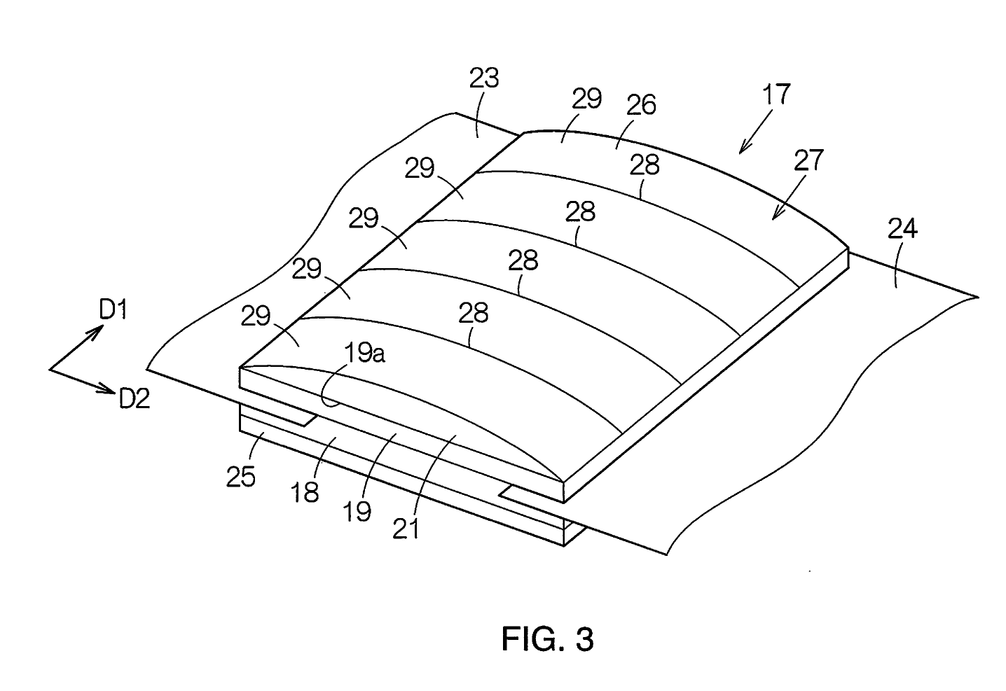

FIG. 3 schematically shows a configuration of the element unit 17. The element unit 17 includes an ultrasonic device 18. As will be described later, the ultrasonic device 18 includes a plurality of ultrasonic transducer elements that are arrayed on a base, such as a substrate. A protection layer 19 is formed on a front surface of the ultrasonic device 18. The protection layer 19 overlies the front surface of the ultrasonic device 18, that is to say, an emission surface from which ultrasonic waves are emitted. The entirety of the acoustic matching layer 19 is attached firmly to the front surface of the ultrasonic device 18. An acoustic lens 21, which is an acoustic matching body, is coupled to a front surface 19a of the protection layer 19. The acoustic lens 21 is formed on the front surface 19a of the protection layer 19. The acoustic lens 21 may be formed integrally with the protection layer 19. The protection layer 19 and the acoustic lens 21 realize matching of acoustic impedances between a test subject, such as a living subject, and the ultrasonic device 18. The acoustic lens 21 plays a role in collecting ultrasonic waves that are simultaneously emitted from the respective ultrasonic transducer elements onto one focus point. Here, the protection layer 19 and the acoustic lens 21 are formed of, for example, silicone resin. Furthermore, a first flexible printed wiring board (hereinafter “first wiring board”) 23 and a second flexible printed wiring board (hereinafter “second wiring board”) 24 are discretely joined to the ultrasonic device 18. The ultrasonic device 18 is lined with a backing member 25.

The acoustic lens 21 includes an acoustic matching unit 26 formed on the front surface 19a of the protection layer 19. The acoustic matching unit 26 includes a base surface, which is an element connection surface that can be connected to ultrasonic wave emission surfaces of the ultrasonic transducer elements. The element connection surface of the acoustic matching unit 26 is overlaid on the front surface 19a of the protection layer 19. The acoustic matching unit 26 has a curved surface 27 that is raised in a convex shape above the element connection surface. The curved surface 27 is formed by generatrices that extend in a first direction D1 parallel to one another. The curved surface 27 is equivalent to a partial cylindrical surface of a cylinder that has a central axis parallel to the generatrices. The curved surface 27 and the base surface face each other.

A plurality of slits 28 are formed in the acoustic matching unit 26. The slits 28 extend in a second direction D2 such that they follow lines of intersections between planes intersecting the generatrices of the curved surface 27 and the curved surface 27. The slits 28 form through holes that pass through between the element connection surface and the curved surface 27. The first direction D1 and the second direction D2 are defined in a plane including, for example, the front surface of the ultrasonic device 18, and are perpendicular to each other. Here, the lines of intersections are defined by the curved surface 27 and planes perpendicular to the generatrices of the curved surface 27.

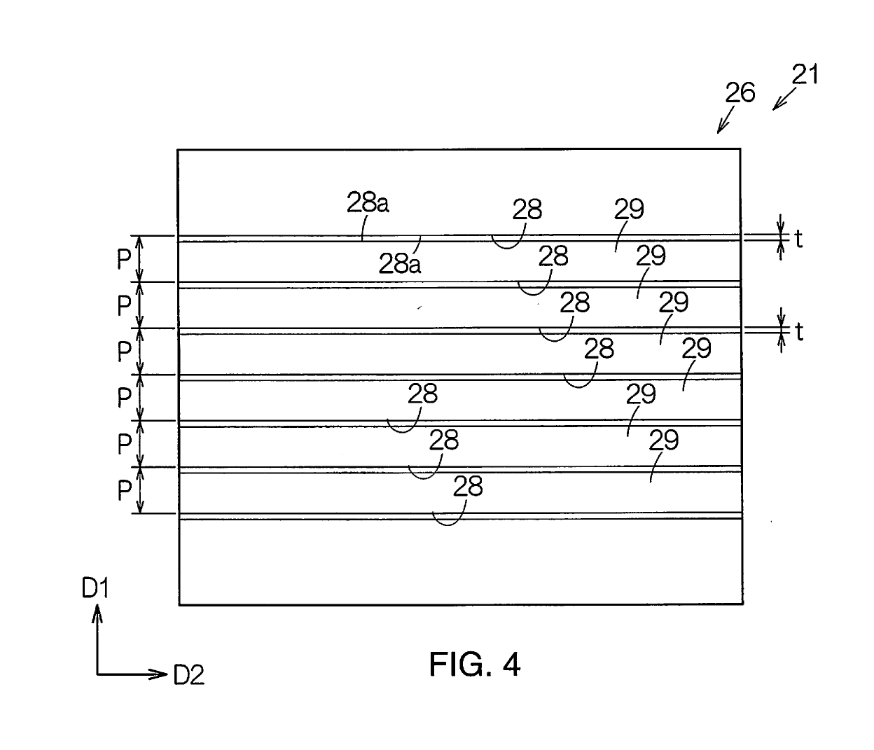

The slits 28 partition the acoustic matching unit 26 across the front surface 19a of the protection layer 19 and the curved surface 27. The acoustic matching unit 26 is accordingly partitioned into a plurality of acoustic matching pieces 29. As shown in FIG. 4, on the front surface 19a of the protection layer 19, an individual acoustic matching piece 29 is demarcated by the curved surface 27 and a pair of planes 28a perpendicular to the generatrices of the curved surface 27. The acoustic matching pieces 29 have generatrices along mutual straight lines, and are arranged on the front surface 19a of the protection layer 19 while being spaced from one another.

Here, any part of the slits 28 is set to have a uniform width t. Therefore, the acoustic matching pieces 29 have an equal clearance therebetween. Alternatively, an individual slit 28 may have irregular widths, and different widths may be set for different slits 28. The acoustic matching pieces 29 are arranged while being spaced by an equal distance from one another in the first direction (a direction parallel to the generatrices) D1. In addition, the acoustic matching pieces 29 are set to have an equal size. Therefore, the acoustic matching pieces 29 are arranged at an equal pitch P. Alternatively, the acoustic matching pieces 29 may have various sizes.

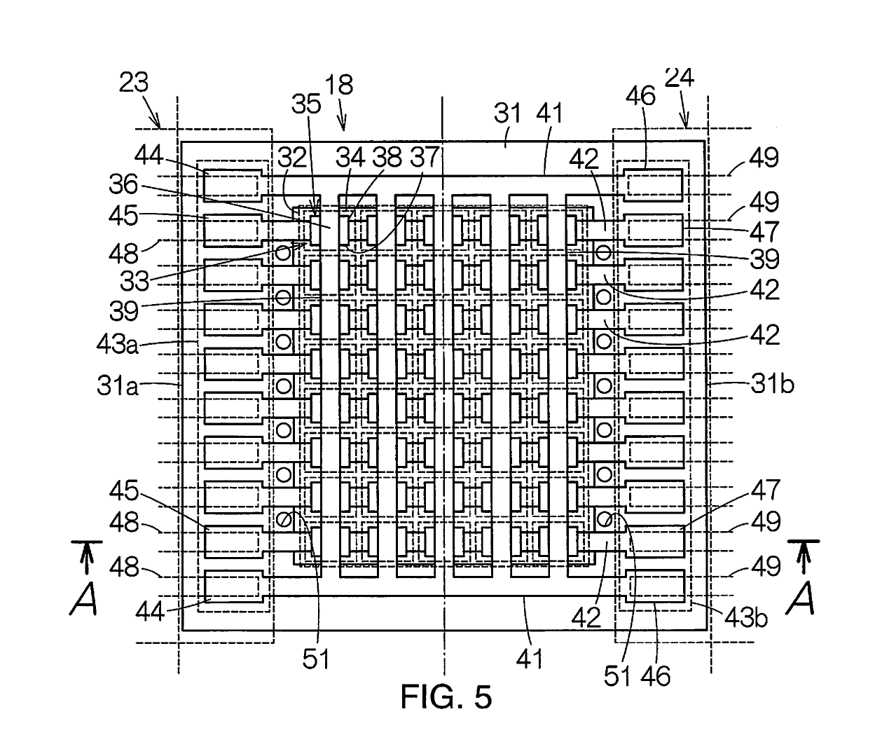

FIG. 5 is a schematic plan view of the ultrasonic device 18. The ultrasonic device 18 includes a base 31. An element array 32 is formed on the base 31. The element array 32 is composed of an array of ultrasonic transducer elements (hereinafter “elements”) 33. The array is a matrix with a plurality of rows and a plurality of columns. Alternatively, a staggered arrangement may be established in the array. In the case of the staggered arrangement, it is sufficient to shift a group of the elements 33 in an even-numbered column by one-half of a row pitch with respect to a group of the elements 33 in an odd-numbered column. Here, the number of elements in one of an odd-numbered column and an even-numbered column may be smaller by one than the number of elements in the other.

The elements 33 have their respective vibrating films 34. In FIG. 5, outlines of the vibrating films 34 are drawn by dashed lines in a plan view in a direction perpendicular to film surfaces of the vibrating films 34 (a plan view in a thickness direction of the substrate). The insides of the outlines are equivalent to inner regions of the vibrating films 34. The outsides of the outlines are equivalent to outer regions of the vibrating films 34. Piezoelectric elements 35 are formed above the vibrating films 34. The piezoelectric elements 35 are composed of upper electrodes 36, lower electrodes 37, and piezoelectric films 38. On a per-element 33 basis, the piezoelectric films 38 are interposed between the upper electrodes 36 and the lower electrodes 37. The lower electrodes 37, the piezoelectric films 38, and the upper electrodes 36 are overlaid in this order. The ultrasonic device 18 is constituted as one piece of ultrasonic transducer element chip.

A plurality of first conductors 39 are formed above the front surface of the base 31. The first conductors 39 extend parallel to one another in a direction of the rows in the array. One first conductor 39 is assigned to one row of the elements 33. One first conductor 39 is connected to the piezoelectric films 38 of the elements 33 aligned in the direction of the rows in the array. On a per-element 33 basis, the first conductors 39 form the upper electrodes 36. The first conductors 39 are connected to a pair of extraction interconnects 41 at both ends. The extraction interconnects 41 extend parallel to each other in a direction of the columns in the array. Therefore, all of the first conductors 39 have the same length. In this way, the upper electrodes 36 are mutually connected throughout all the elements 33 in the matrix. The first conductors 39 can be formed of, for example, iridium (Ir). Alternatively, other conductive materials may be used for the first conductors 39.

A plurality of second conductors 42 are also formed above the front surface of the base 31. The second conductors 42 extend parallel to one another in the direction of the columns in the array. One second conductor 42 is assigned to one column of the elements 33. One second conductor 42 is provided to the piezoelectric films 38 of the elements 33 aligned in the direction of the columns in the array. On a per-element 33 basis, the second conductors 42 form the lower electrodes 37. For example, a multilayer film of titanium (Ti), iridium (Ir), platinum (Pt), and titanium (Ti) can be used for the second conductors 42. Alternatively, other conductive materials may be used for the second conductors 42.

Electric current to the elements 33 is switched on a per-column basis. A line scan and a sector scan are realized in accordance with such switching of electric current. As one column of the elements 33 outputs ultrasonic waves simultaneously, the number in one column, that is to say, the number of rows in the array can be determined in accordance with the output level of the ultrasonic waves. It is sufficient to set the number of rows to, for example, approximately ten to fifteen. In FIG. 5, the rows are partially omitted, and five rows are drawn. The number of columns in the array can be determined in accordance with the breadth of the range of the scan. It is sufficient to set the number of columns to, for example, 128 or 256. In FIG. 5, the columns are partially omitted, and eight columns are drawn. The roles of the upper electrodes 36 and the roles of the lower electrodes 37 may be interchanged. That is to say, the lower electrodes may be mutually connected throughout all the elements 33 in the matrix, whereas the upper electrodes may be mutually connected one-to-one to columns of the elements 33 in the array.

An outline of the base 31 includes a first edge 31a and a second edge 31b facing each other. The first edge 31a and the second edge 31b are separated by a pair of straight lines that are parallel to each other. One line of a first terminal array 43a is arranged between the first edge 31a and an outline of the element array 32. One line of a second terminal array 43b is arranged between the second edge 31b and the outline of the element array 32. The first terminal array 43a can form one line parallel to the first edge 31a. The second terminal array 43b can form one line parallel to the second edge 31b. The first terminal array 43a is composed of a pair of upper electrode terminals 44 and a plurality of lower electrode terminals 45. Similarly, the second terminal array 43b is composed of a pair of upper electrode terminals 46 and a plurality of lower electrode terminals 47. One extraction interconnect 41 is connected to an upper electrode terminal 44 and an upper electrode terminal 46 at its respective ends. It is sufficient for the extraction interconnects 41 and the upper electrode terminals 44 and 46 to have plane symmetry with respect to a vertical plane bisecting the element array 32. One second conductor 42 is connected to a lower electrode terminal 45 and a lower electrode terminal 47 at its respective ends. It is sufficient for the second conductors 42 and the lower electrode terminals 45 and 47 to have plane symmetry with respect to a vertical plane bisecting the element array 32. Here, the outline of the base 31 has a rectangular shape. Alternatively, the outline of the base 31 may have a square shape or a trapezoidal shape.

The first wiring board 23 covers the first terminal array 43a. First signal lines 48, which are conductive wires, are formed at one end of the first wiring board 23 in one-to-one correspondence with the upper electrode terminals 44 and the lower electrode terminals 45. The first signal lines 48 face and are joined to the upper electrode terminals 44 and the lower electrode terminals 45 in one-to-one correspondence. Similarly, the second wiring board 24 covers the second terminal array 43b. Second signal lines 49, which are conductive wires, are formed at one end of the second wiring board 24 in one-to-one correspondence with the upper electrode terminals 46 and the lower electrode terminals 47. The second signal lines 49 face and are joined to the upper electrode terminals 46 and the lower electrode terminals 47 in one-to-one correspondence.

Through holes 51 are formed in the base 31 of the ultrasonic device 18. The through holes 51 open to the front surface of the base 31. The openings of the through holes 51 are arranged in a line between the outline of the element array 32 and the first wiring board 23, and between the outline of the element array 32 and the second wiring board 24.

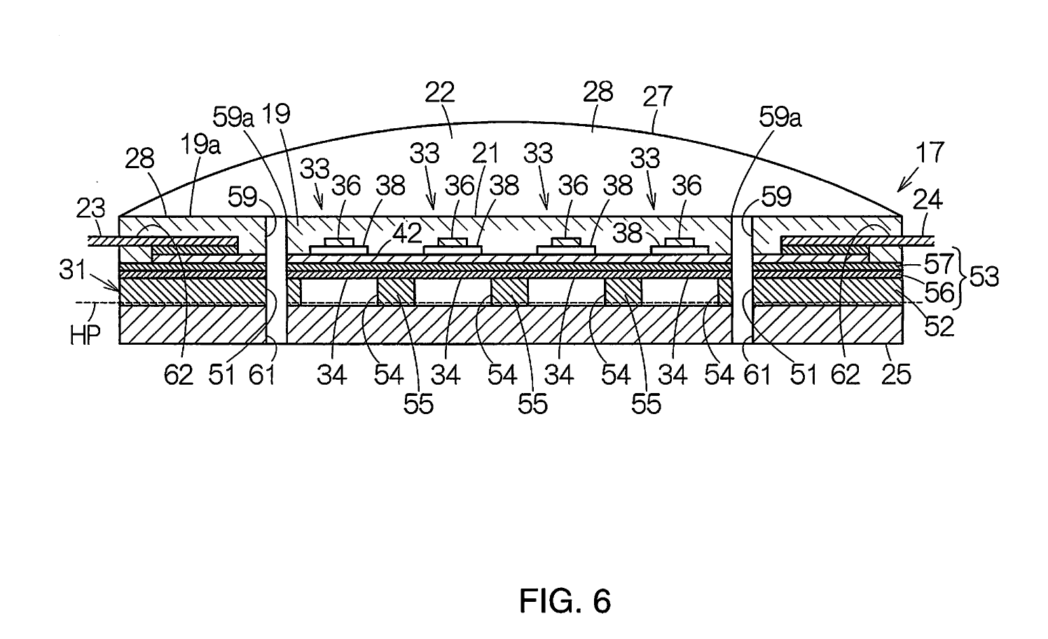

As shown in FIG. 6, the base 31 includes a substrate 52 and a flexible film 53. The flexible film 53 is formed across an entire front surface of the substrate 52. In the substrate 52, openings 54 are formed in one-to-one correspondence with the elements 33. An array of openings 54 is arranged in the substrate 52. An outline of a region in which the openings 54 are arranged is equivalent to the outline of the element array 32. Any two neighboring openings 54 are demarcated by a dividing wall 55 provided therebetween. Neighboring openings 54 are separated by the dividing wall 55. A wall thickness of the dividing wall 55 is equivalent to a distance between neighboring openings 54. The dividing wall 55 defines two wall surfaces in planes that extend parallel to each other. The wall thickness is equivalent to a distance between the two wall surfaces. That is to say, the wall thickness can be defined as a length of a perpendicular line segment that is perpendicular to the wall surfaces and interposed between the wall surfaces. It is sufficient for the substrate 52 to be formed of, for example, a silicon substrate.

The flexible film 53 is composed of a silicon oxide (SiO₂) layer 56 stacked onto the front surface of the substrate 52, and a zirconium oxide (ZrO₂) layer 57 stacked onto a front surface of the silicon oxide layer 56. The flexible film 53 is in contact with the openings 54. In this manner, parts of the flexible film 53 form the vibrating films 34 in correspondence with outlines of the openings 54. Specifically, the vibrating films 34 are parts of the flexible film 53 that face the openings 54 and hence can exert film vibration in a thickness direction of the substrate 52. The film thickness of the silicon oxide layer 56 can be determined on the basis of the resonance frequency.

The lower electrodes 37, the piezoelectric films 38, and the upper electrodes 36 are stacked in order above front surfaces of the vibrating films 34. The piezoelectric films 38 can be formed of, for example, lead zirconate titanate (PZT). Alternatively, other piezoelectric materials may be used for the piezoelectric films 38. Here, the piezoelectric films 38 completely overlie the second conductors 42 below the first conductors 39. Due to the action of the piezoelectric films 38, a short circuit can be prevented between the first conductors 39 and the second conductors 42.

The backing member 25 is fixed on a back surface of the base 31. The back surface of the base 31 is overlaid on a front surface of the backing member 25. The backing member 25 closes the openings 54 at a back surface of the ultrasonic device 18. The backing member 25 can include a rigid base substrate. Here, the dividing walls 55 are coupled to the backing member 25. An individual dividing wall 55 is joined to the backing member 25 via at least one joining region. The joining can be performed using an adhesive agent.

The protection layer 19 is stacked onto the front surface of the base 31. For example, the protection layer 19 covers the entirety of front surface of the base 31. As a result, the protection layer 19 overlies the element array 32, the first and second terminal arrays 43a and 43b, and the first and second wiring boards 23 and 24. The protection layer 19 protects a configuration of the element array 32, a joint between the first terminal array 43a and the first wiring board 23, and a joint between the second terminal array 43b and the second wiring board 24.

Through holes 59 are formed in the protection layer 19. The through holes 59 extend in a direction perpendicular to the front surface of the base 31 of the ultrasonic device 18. For example, a pair of through holes 59 is assigned to an individual slit 28. One end of a through hole 59 communicates with a slit 28, and forms a supply opening 59a in a space within the slit 28. The other end of the through hole 59 communicates with a through hole 51 in the base 31. Similarly, through holes 61 are formed in the backing member 25. The through holes 61 extend in a direction perpendicular to the front surface of the base 31 of the ultrasonic device 18. One end of a through hole 61 communicates with a through hole 51. The other end of the through hole 61 is connected to, for example, a supply source of the acoustic coupling material (not shown in the drawings). The acoustic coupling material is supplied to the passages at, for example, a predetermined pressure.

2. Operations of Ultrasonic Diagnostic Device

The following is a brief description of the operations of the ultrasonic diagnostic device 11. In order to transmit ultrasonic waves, pulse signals are supplied to the piezoelectric elements 35. The pulse signals are supplied to the elements 33 via the lower electrode terminals 45 and 47 and via the upper electrode terminals 44 and 46 on a per-column basis. An electric field acts on the piezoelectric films 38 between the lower electrodes 37 and the upper electrodes 36 on a per-element 33 basis. The piezoelectric films 38 vibrates at ultrasonic frequency. Vibrations of the piezoelectric films 38 propagate to the vibrating films 34. In this way, the ultrasonic waves cause the vibrating films 34 to vibrate. As a result, desired ultrasonic beams are emitted toward a subject (e.g., the interior of a human body).

Reflected waves of the ultrasonic waves cause the vibrating films 34 to vibrate. Ultrasonic vibrations of the vibrating films 34 cause ultrasonic vibrations of the piezoelectric films 38 at a desired frequency. Current is output from the piezoelectric elements 35 in accordance with the piezoelectric effect of the piezoelectric elements 35. An electric voltage is generated between the upper electrodes 36 and the lower electrodes 37 on a per-element 33 basis. Current is output as electrical signals from the lower electrode terminals 45 and 47 and from the upper electrode terminals 44 and 46. In this way, the ultrasonic waves are detected.

Transmission and reception of the ultrasonic waves are repeated. Consequently, a line scan and a sector scan are realized. When the scan is complete, an image is formed on the basis of digital signals of output signals. The image thus formed is displayed on the screen of the display panel 15.

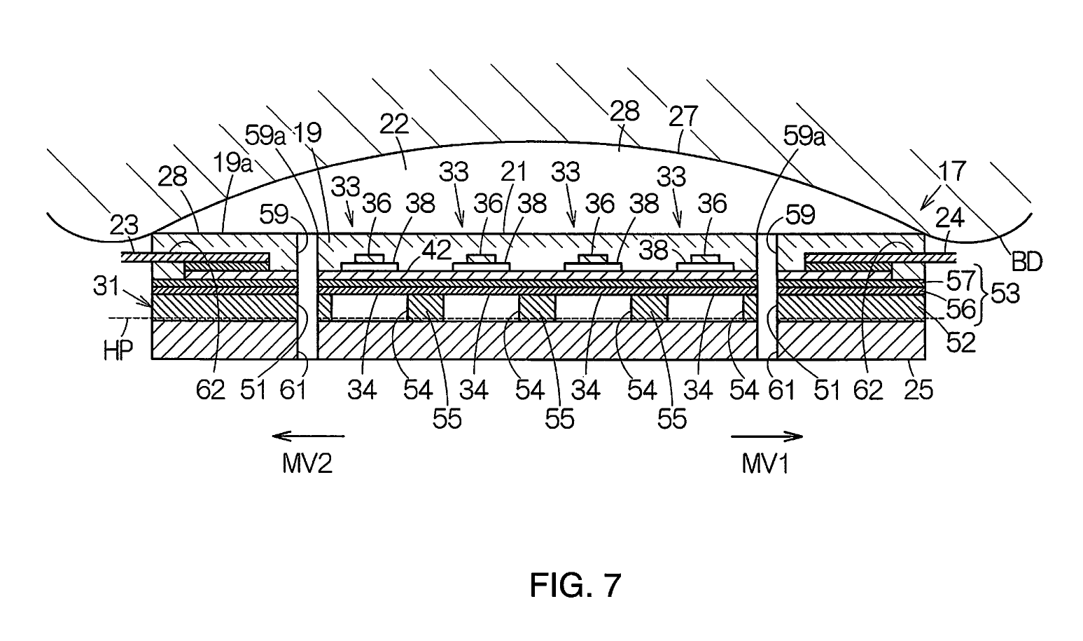

As shown in FIG. 7, when the ultrasonic probe 13 is pressed against a surface of a body BD for ultrasonic diagnosis, the curved surface 27 of the acoustic lens 21 comes into close contact with the surface of the body BD. When the acoustic coupling material (medium), such as water, is supplied from the supply openings 59a of the through holes 59, the slits 28 are filled with the water. The slits 28 function as passages for the water. Even when the curved surface 27 is pressed against the soft surface of the body BD, the water can spread across the entire slits 28. Thereafter, the water overflows from the slits 28 onto the curved surface 27. The water can accordingly spread along the curved surface 27. In this way, the water is sufficiently supplied to the curved surface 27, that is to say, the outer front surface in an effective area of the acoustic lens 21. The water can be sufficiently distributed between the effective area of the curved surface 27 and the surface of the body BD.

The ultrasonic probe 13 is moved along the surface of the body BD. In this manner, a target body tissue is searched for. At this time, even when the acoustic lens 21 moves in directions MV1 and MV2 that are perpendicular to the generatrices of the curved surface 27, the water can be supplied from the supply openings 59a of the through holes 59 on a front side in a direction of the movement of the ultrasonic probe 13. Even during the movement, the spacing between the curved surface 27 and the surface of the body BD can be sufficiently filled with the water.

As has been described earlier, a slit 28 is interposed between planes 28a perpendicular to the generatrices of the curved surface 27. The water spreads along the planes 28a perpendicular to the generatrices, and then is supplied to the curved surface 27. In this way, the water can be effectively supplied from the slits 28 to the curved surface 27. As the planes 28a are perpendicular to the generatrices of the curved surface 27, the areas of surfaces of neighboring acoustic matching pieces 29 facing each other (planes 28a) can be suppressed to the minimum. Consequently, the water can efficiently spread between the acoustic matching pieces 29. Furthermore, as the acoustic matching pieces 29 have an equal clearance therebetween, the water can be distributed evenly between neighboring acoustic matching pieces 29. In this way, the water can be supplied thoroughly to the curved surface 27 along the entire lengths of lines of intersections formed by the curved surface 27 and the planes 28a. In addition, as the acoustic matching pieces 29 are arranged at an equal pitch P, the water can be distributed thoroughly in the direction of the generatrices.

(3) Element Units According to Modification Examples

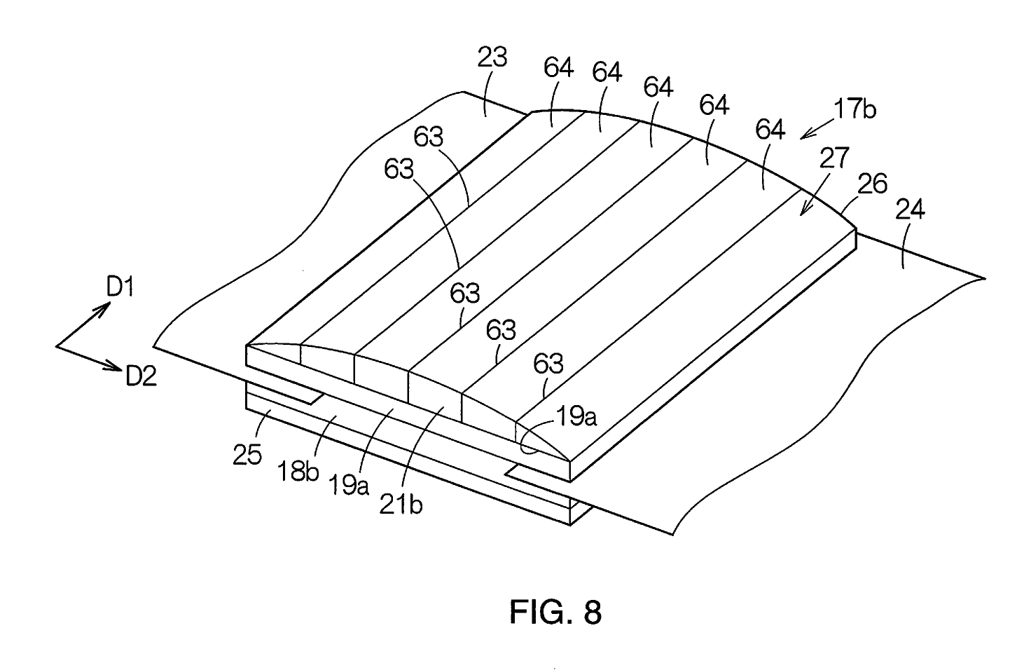

FIG. 8 schematically shows an element unit 17b according to a modification example. In an acoustic lens 21b of the element unit 17b, slits 63 are formed such that they are interposed between planes that are parallel to the generatrices of the curved surface 27. The slits 63 partition the acoustic matching unit 26 across a front surface 19a of a protection layer 19b and the curved surface 27. The acoustic matching unit 26 is accordingly partitioned into a plurality of acoustic matching pieces 64. On the front surface 19a of the protection layer 19b, an individual acoustic matching piece 64 is demarcated by the curved surface 27 and a pair of planes parallel to the generatrices of the curved surface 27. An individual acoustic matching piece 64 has the curved surface 27 demarcated by a pair of generatrices. The acoustic matching pieces 64 are spaced from one another on the front surface 19a of the protection layer 19b. Other configurations of the slits are similar to those of the slits 28.

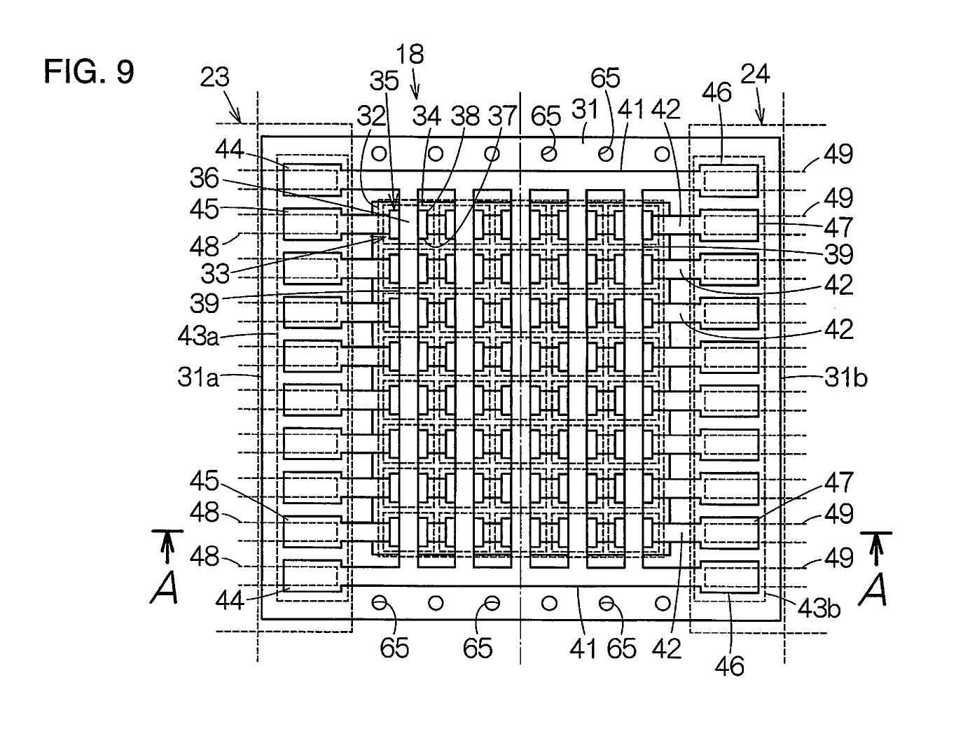

As shown in FIG. 9, in the base 31 of an ultrasonic device 18b, through holes 65 are formed outside the element array 32 between the outline of the element array 32 and edges other than the first edge 31a and the second edge 31b. Similarly to the above-described case, through holes are formed in the protection layer 19b and in the backing member 25, coaxially with and in correspondence with the through holes 65. The sequence of the through holes forms fluid passages. An individual through hole 65 communicates with a supply opening that opens to a space within a slit 63. When the ultrasonic probe 13 is moved parallel to the generatrices of the curved surface 27 in order to search for a body tissue, the water can be supplied from the supply openings on a front side in a direction of the movement of the ultrasonic probe 13. Even during the movement, the spacing between the curved surface 27 and the surface of the body BD can be sufficiently filled with the water.

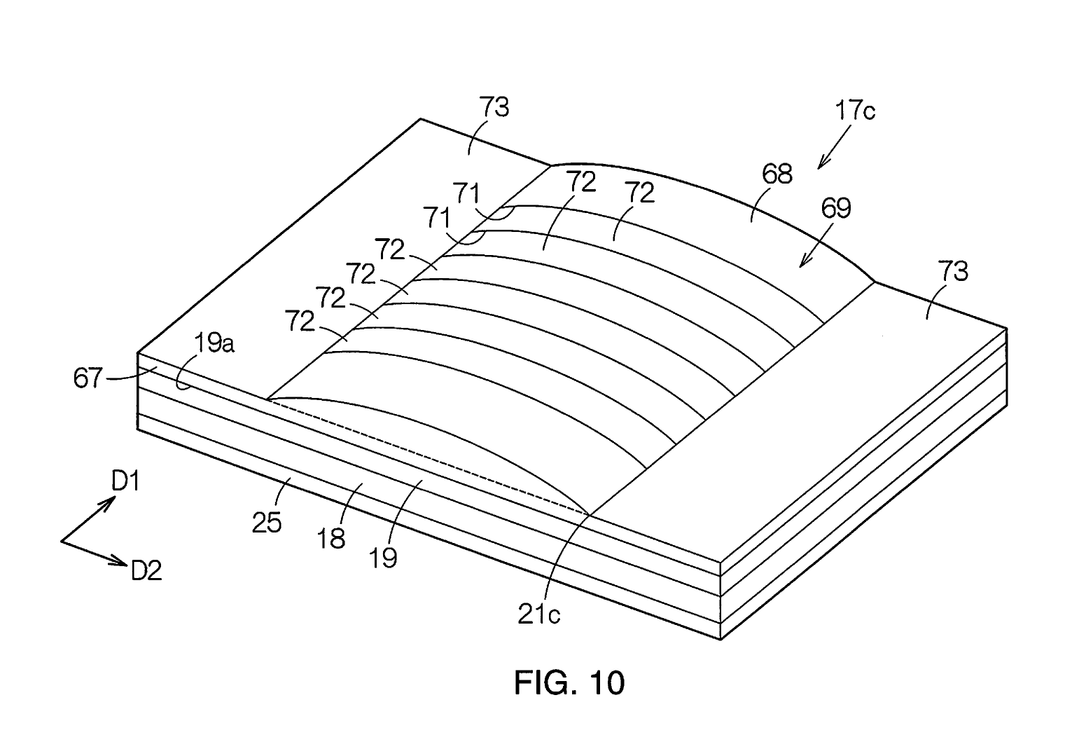

FIG. 10 schematically shows an element unit 17c according to another modification example. In the element unit 17c, an acoustic lens 21c includes a base layer 67. The base layer 67 is overlaid on the front surface 19a of the protection layer 19. An acoustic matching unit 68 is overlaid on a front surface of the base layer 67. The acoustic matching unit 68 has a curved surface 69 that is raised in a convex shape above a virtual plane. Here, the virtual plane overlies the front surface of the base layer 67. The curved surface 69 is formed by generatrices that extend in the first direction D1 parallel to one another. The curved surface 69 is equivalent to a partial cylindrical surface of a cylinder that has a central axis parallel to the generatrices.

A plurality of slits 71 are formed in the acoustic matching unit 68. Similarly to the above-described case, the slits 71 extend in the second direction D2 such that they follow lines of intersections between planes perpendicular to the generatrices of the curved surface 69 and the curved surface 69. The slits 71 partition the acoustic matching unit 68 across the front surface of the base layer 67 and the curved surface 69. The acoustic matching unit 68 is accordingly partitioned into a plurality of acoustic matching pieces 72. On the front surface of the base layer 67, an individual acoustic matching piece 72 is demarcated by the curved surface 69 and a pair of planes perpendicular to the generatrices of the curved surface 69. The acoustic matching pieces 72 have mutual generatrices, and are separated from one another on the front surface of the base layer 67.

The base layer 67 forms a frame 73. The frame 73 extends toward the outside of the curved surface 69 from the following generatrices: a generatrix located at one end of a line of intersection on the curved surface 69, and a generatrix located at the other end of the line of intersection. In the case where the slits 71 end at the front surface of the base layer 67, the base layer 67 joins the acoustic matching pieces 72 to one another. In this way, the acoustic matching pieces 72 are concurrently supported by the base layer 67. Alternatively, the slits 71 may penetrate into the base layer 67 on the inner side of the frame 73. In this case, the acoustic matching pieces 72 are concurrently supported by the frame 73 in a grid fashion.

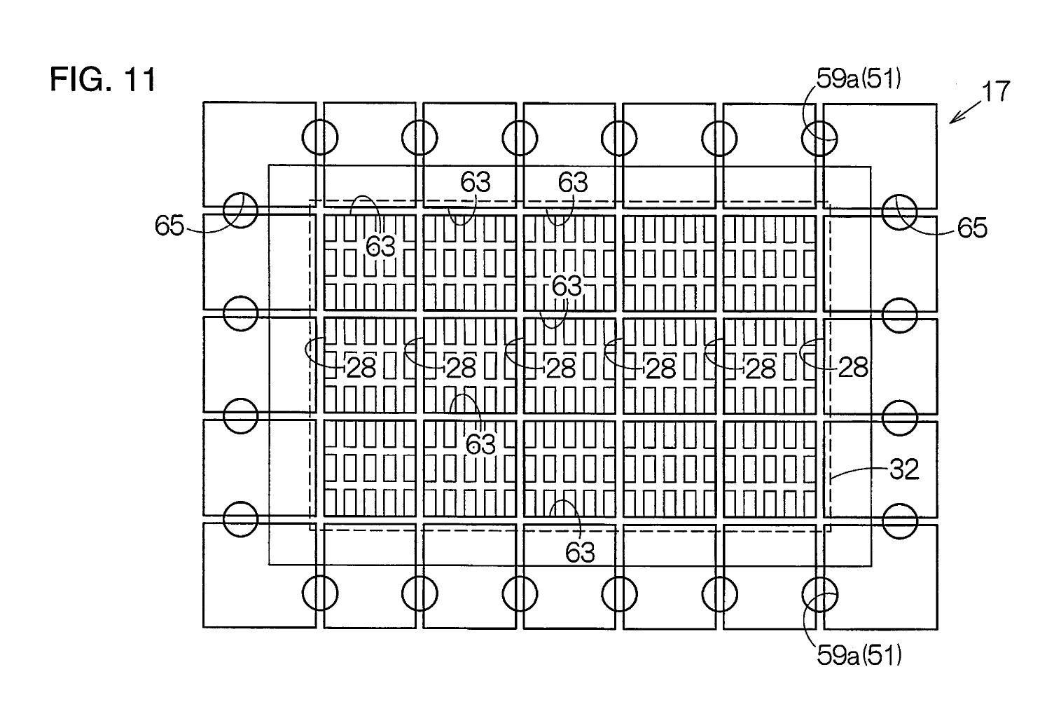

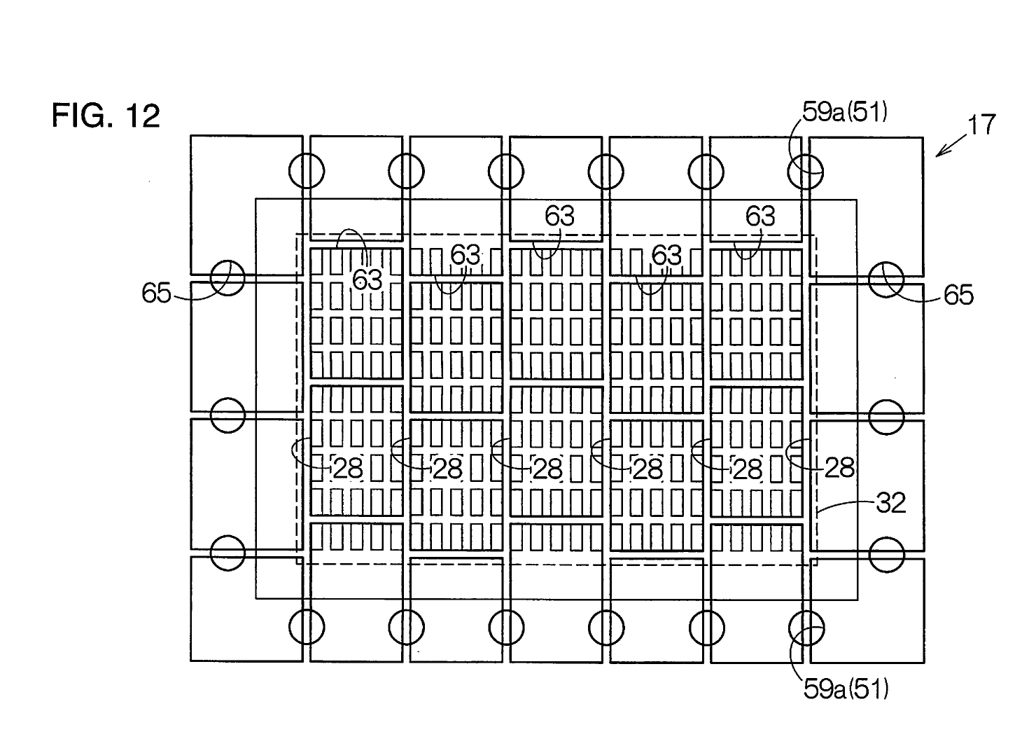

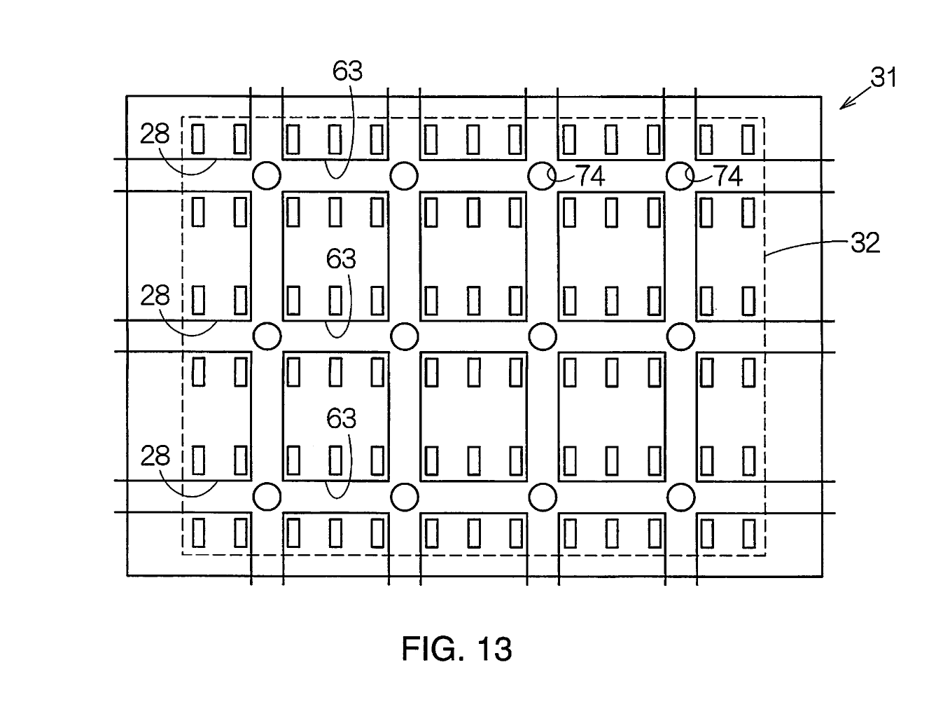

Alternatively, as shown in FIG. 11, the slits 28 and 63 may be formed such that they are interposed between pairs of planes perpendicular to the generatrices of the curved surface 27, and between pairs of planes that extend parallel to the generatrices of the curved surface. Alternatively, as shown in FIG. 12, the positions of the slits 28 and 63 may be shifted in a crank shape. Alternatively, in the base 31, through holes 74 may be formed inside the element array 32 as shown in FIG. 13.

4. Ultrasonic Probe According to Second Embodiment

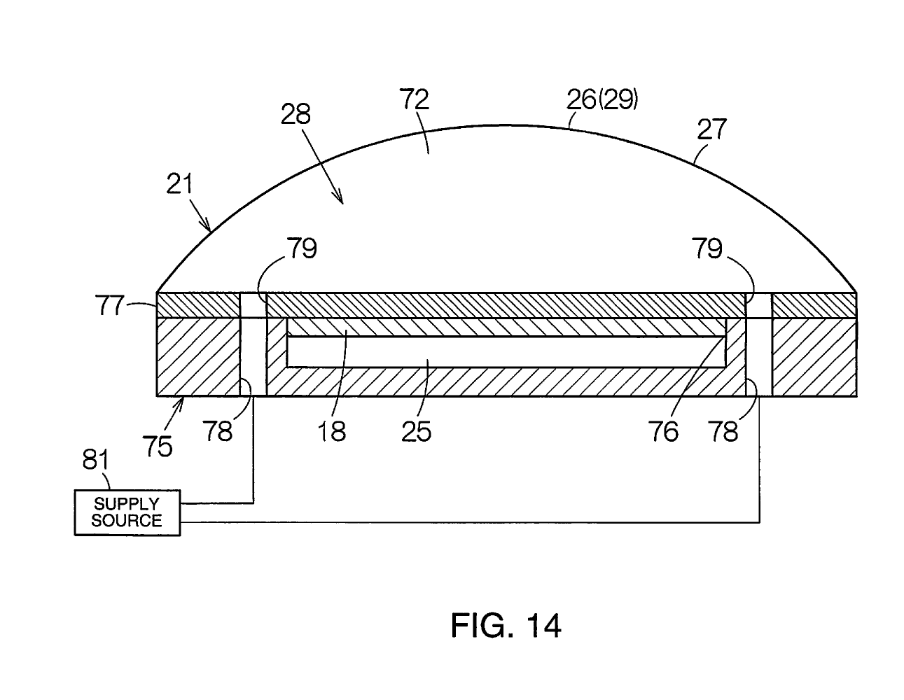

FIG. 14 schematically shows a part of an ultrasonic probe 13x according to a second embodiment. The ultrasonic probe 13x includes a fixture board 75 that supports the ultrasonic device 18 and the backing member 25. The fixture board 75 may be, for example, embedded in the probe head 13b or formed integrally with the housing 16. A recess 76 is formed in the fixture board 75. The ultrasonic device 18 and the backing member 25 fit in the recess 76. The front surface of the ultrasonic device 18 is flush and continuous with a front surface of the fixture board 75. The front surface of the fixture board 75 extends outward from an outline of the ultrasonic device 18.

A protection layer 77 is coupled to the front surface of the ultrasonic device 18 and to the front surface of the fixture board 75. The protection layer 77 extends not only across the front surface of the ultrasonic device 18, but also across the front surface of the fixture board 75. The acoustic matching unit 26 is formed on a front surface 77a of the protection layer 77. Similarly to the above-described case, the slits 28 are formed in the acoustic matching unit 26. Configurations of the curved surface 27 and the slits 28 are similar to those described above.

In the fixture board 75, through holes 78 are formed around the ultrasonic device 18, that is to say, outside the outline of the ultrasonic device 18, in a plan view. The through holes 78 extend in a direction perpendicular to a virtual plane including the front surface of the ultrasonic device 18. Through holes 79 are formed in the protection layer 77 in correspondence with the through holes 78 in the fixture board 75. The through holes 79 penetrate through the protection layer 77. The through holes 79 are continuous with the through holes 78. Distal ends of the through holes 79 open to the corresponding slits 28. A supply source 81 of the acoustic coupling material is connected to the through holes 78 in the fixture board 75. The through holes 78 and 79 function as emission units for emitting the acoustic coupling material. Other configurations are similar to those according to the first embodiment.

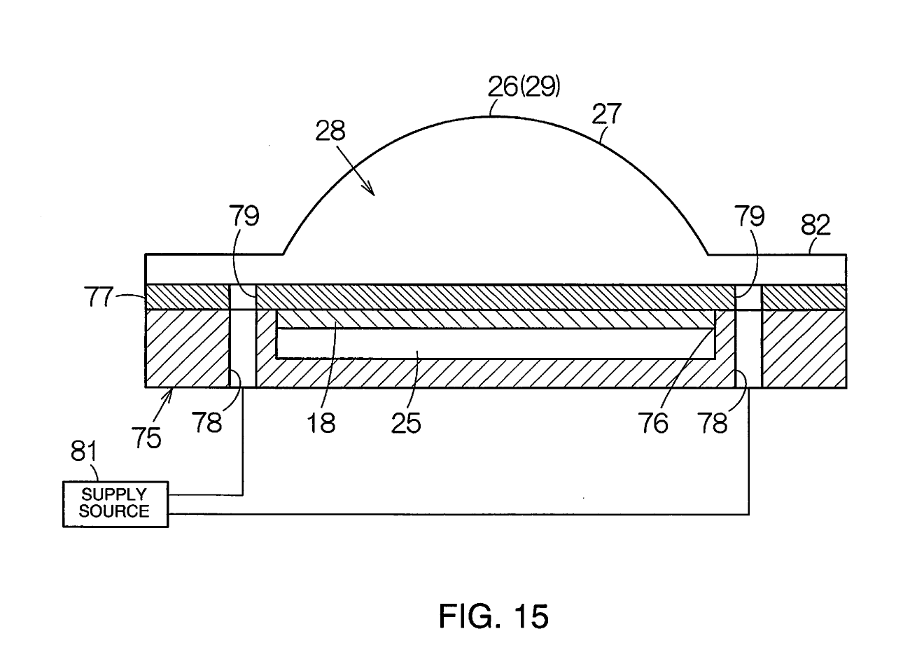

In the present case also, the acoustic matching unit 26 may include a frame 82 formed around the curved surface 27 as shown in, for example, FIG. 15. The frame 82 is overlaid above the front surface of the fixture board 75. Here, the slits 28 may extend to the frame 82. The curved surface 27 is formed in accordance with the breadth of the ultrasonic device 18.

While the present embodiments have been described above in detail, a person skilled in the art should easily understand that many modifications are possible without substantially departing from new matters and effects of the invention. Therefore, all examples of such modifications are to be embraced within the scope of the invention. For example, terms that are used at least once in the description or the drawings in conjunction with different terms having broader or similar meanings can be replaced with the different terms in any portion of the description or the drawings. Furthermore, the configurations and operations of the ultrasonic diagnostic device 11, the ultrasonic probe 13, the element units 17, 17b, and 17c, the elements 33, the acoustic lens 21, and the like are not limited to those described in the present embodiments. They can be implemented with various modifications.

The entire disclosure of Japanese Patent Application No. 2013-075339, filed Mar. 29, 2013 is expressly incorporated by reference herein.

What is claimed is:

1. An acoustic matching body comprising:
an element connection surface connectable to an ultrasonic wave emission surface of an ultrasonic transducer element;
a curved surface that has a shape of a convexity above the element connection surface and is formed by generatrices parallel to one another; and
a slit-like through hole that passes through between the element connection surface and the curved surface.

2. The acoustic matching body according to claim 1, wherein
an inner surface of the slit-like through hole has two planes that are perpendicular to the generatrices of the curved surface.

3. The acoustic matching body according to claim 2, further comprising
a supply opening that communicates with the slit-like through hole is located at a position outside a region in which the ultrasonic transducer element is arranged in a plan view in a direction normal to the element connection surface.

4. The acoustic matching body according to claim 1, wherein
an inner surface of the slit-like through hole has two planes that are parallel to the generatrices of the curved surface.

5. The acoustic matching body according to claim 4, further comprising
a supply opening that communicates with the slit-like through hole is located at a position outside a region in which the ultrasonic transducer element is arranged in a plan view in a direction normal to the element connection surface.

6. An acoustic matching body comprising
a plurality of acoustic matching pieces that have convex curved surfaces formed by generatrices parallel to one another, base surfaces facing the curved surfaces and parallel to the generatrices, and two planes intersecting the generatrices, wherein
the curved surfaces of the acoustic matching pieces have the generatrices on mutual straight lines, and
the base surfaces of the acoustic matching pieces are arranged on a mutual plane while being spaced from one another.

7. The acoustic matching body according to claim 6, wherein
the two planes are perpendicular to the generatrices.

8. The acoustic matching body according to claim 6, wherein
the plurality of acoustic matching pieces are arranged while being spaced by an equal distance from one another in a direction parallel to the generatrices.

9. The acoustic matching body according to claim 8, wherein
the plurality of acoustic matching pieces are arranged at an equal pitch in a direction of the generatrices.

10. The acoustic matching body according to claim 6, further comprising
a base layer that concurrently supports the plurality of acoustic matching pieces, with a front surface of the base layer overlying the base surfaces.

11. The acoustic matching body according to claim 10, wherein
a through hole is formed in the base layer, the through hole penetrating through the base layer and opening to a position between the plurality of acoustic matching pieces.

12. The acoustic matching body according to claim 6, further comprising
a frame that is located on outer sides of both end portions of the curved surfaces in a direction perpendicular to the generatrices, and joins the acoustic matching pieces to one another.

13. An ultrasonic probe comprising the acoustic matching body according to claim 1.

14. The ultrasonic probe according to claim 13, further comprising
an emission unit that emits an acoustic coupling material.

15. An ultrasonic imaging device comprising the acoustic matching body according to claim 1.

16. The ultrasonic imaging device according to claim 15, further comprising
an emission unit that emits an acoustic coupling material.
